(19) United States
(12) Patent Application Publication
(10) Pub. No.: US 2022/0373714 A1
(43) Pub. Date: Nov. 24, 2022

(54) TERAHERTZ SENSOR BASED ON DIELECTRIC METASURFACE

(71) Applicant: Anhui University, Hefei (CN)

(72) Inventors: Ming FANG, Hefei (CN); Meijun KANG, Hefei (CN); Jian FENG, Hefei (CN); Ke XU, Hefei (CN); Zhicheng XIAO, Hefei (CN); Rongsheng CHENG, Hefei (CN); Xingchen LIU, Hefei (CN); Zhixiang HUANG, Hefei (CN)

(21) Appl. No.: 17/882,749

(22) Filed: Aug. 8, 2022

(30) Foreign Application Priority Data
Aug. 16, 2021 (CN) 202110940220.2

(51) Int. Cl. G02B 1/00

(52) U.S. Cl. CPC G02B 1/002

(57) ABSTRACT

A terahertz sensor based on a dielectric metasurface, including a sensing element, and a thermosensitive circuit connected to the sensing element. The sensing element is composed of a cylindrical semiconductor doped with a conductive material. The conductive material is configured to change conductivity of the cylindrical semiconductor to enable the cylindrical semiconductor to absorb electromagnetic waves in terahertz region.

### CROSS-REFERENCE TO RELATED APPLICATIONS

This application claims the benefit of priority from Chinese Patent Application No. 202110940220.2, filed on Aug. 16, 2021. The content of the aforementioned application, including any intervening amendments thereto, is incorporated herein by reference.

### TECHNICAL FIELD

This application relates to sensor manufacturing, in particular to a terahertz sensor based on a dielectric metasurface.

### BACKGROUND

The electromagnetic metamaterial is an artificially-synthesized special material, and has been widely investigated and applied due to its extremely high absorption rate of electromagnetic waves in certain bands under certain conditions.

In recent years, with the rapid development of the internet informatization, more and more electronic products have emerged, and electromagnetic waves are gradually applied in people's daily life, for example, electromagnetic waves can be combined with a sensor. The sensor is indispensable for many fields, such as household appliances (i.e., induction cooker, refrigerator, and microwave oven), medical treatment, military, and e-commerce logistics.

The traditional sensor is composed of metal and a medium, and has a high manufacturing cost. Moreover, a large power is needed since the working band of the traditional sensor is from dozens to hundreds of megahertz, which causes the generation of extremely high heat, thereby greatly influencing the adjacent components and the efficiency of the sensor, and shortening the service life of the whole product.

### SUMMARY

To overcome the above-mentioned deficiencies in the prior art, this disclosure provides a terahertz sensor based on a dielectric metasurface, which has low heat generation and less influence on the surrounding components. Moreover, it also has simple structure, easy manufacturing, and high sensitivity.

Technical solutions of this application are specifically described as follows.

The disclosure provides a terahertz sensor based on a dielectric metasurface, which is made of a dielectric semiconductor material. The conductivity of the terahertz sensor is improved by doping to enable the terahertz sensor to absorb electromagnetic waves in a certain region.

To be specific, this application provides a terahertz sensor based on a dielectric metasurface, comprising:

a sensing element; and

a thermosensitive circuit connected to the sensing element;

wherein the sensing element is composed of a cylindrical semiconductor doped with a conductive material; the conductive material is configured to change electrical conductivity of the cylindrical semiconductor to enable the cylindrical semiconductor to absorb electromagnetic waves in terahertz region. Since the medium used in the sensing element of the sensor is a doped semiconductor, the heat generated by the semiconductor is far lower than that of the metal, so that the influence of generated heat on the surrounding device is also relatively low.

In some embodiments, the terahertz sensor is micron-sized.

In some embodiments, the conductive material is boron.

In some embodiments, the cylindrical semiconductor is a silicon nitride cylinder.

In some embodiments, the silicon nitride cylinder has a radius of 95-110 um and a height of 85-95 um.

In some embodiments, the cylindrical semiconductor doped with the conductive material is prepared through steps of:

(S1) pretreating a cylindrical silicon nitride substrate;

(S2) subjecting a boron target to magnetron co-sputtering in argon to deposit a boron-doped silicon nitride film on the cylindrical silicon nitride substrate, wherein during the magnetron co-sputtering, the cylindrical silicon nitride substrate is subject to a bias voltage; and

(S3) subjecting the cylindrical silicon nitride substrate to photo-thermal annealing under nitrogen gas for 1-2 h; and

(S4) cooling the cylindrical silicon nitride substrate to obtain a boron-doped cylindrical semiconductor.

Compared with the prior art, the beneficial effects of the present disclosure are described below.

(1) The terahertz sensor provided herein can be operated under a relatively low power, thereby reducing the electricity consumption.

(2) The terahertz sensor provided herein has small size, regular shape, and convenient fabrication.

(3) The terahertz sensor provided herein has less energy loss and heat generation.

(4) The terahertz sensor provided herein can be used in various frequency bands by modifying the relative dielectric constant, conductivity, and size of the dielectric.

(5) The traditional sensors generally have relatively high cost due to the use of precious metal, and by comparison, the semiconductor adopted in the terahertz sensor provided herein has low cost and simple manufacturing process.

### BRIEF DESCRIPTION OF THE DRAWINGS

FIG. 1 schematically illustrates a simulation model of a terahertz sensor according to an embodiment of the present disclosure;

FIG. 2 is a resonance curve of the simulation model of the terahertz sensor according to an embodiment of the present disclosure;

FIG. 3a is a Y-direction electric field plot of the simulation model of the terahertz sensor according to an embodiment of the present disclosure;

FIG. 3b is an X-direction electric field plot of the simulation model of the terahertz sensor according to an embodiment of the present disclosure;

FIG. 4a shows change of thermal conductivity (k) of Si₃N₄ with temperature;

FIG. 4b shows change of constant pressure heat capacity (Cp) of Si₃N₄ with temperature; and

FIG. 5 shows surface temperature of the terahertz sensor according to an embodiment of the present disclosure.

### DETAILED DESCRIPTION OF EMBODIMENTS

The technical solutions in the embodiments of the present disclosure will be clearly and completely described below with reference to the accompanying drawings. All other embodiments obtained by one of ordinary skill in the art based on the embodiments of the present disclosure without paying any creative efforts shall fall within the scope of the present disclosure.

The terahertz sensor in this application achieves the required wave absorption performance based on single resonance unit, that is, the terahertz sensor only includes one wave-absorbing resonance unit. As shown in FIG. 1, the resonance unit is Si₃N₄, in which a conductive material is doped to impart a certain conductivity to the Si₃N₄. After being directly and vertically incident on the surface of the resonance unit, the electromagnetic waves will be absorbed to generate electromagnetic heat in the form of dielectric loss and conduction loss. Then the generated electromagnetic heat will affect the impedance of the thermistor attached below (not illustrated in FIG. 1), leading to the impedance change in the circuit of the thermistor. The circuit plays a role as a temperature control sensor in some mechanical automatic operations.

Inspired by the above working principle, this application provides a terahertz sensor based on a dielectric metasurface, which includes a sensing element, and a thermosensitive circuit connected to the sensing element. The sensing element is composed of a cylindrical semiconductor doped with a conductive material. The conductive material is configured to change conductivity of the cylindrical semiconductor to enable the cylindrical semiconductor to absorb electromagnetic waves in terahertz region.

Preferably, the terahertz sensor is micron-sized.

Preferably, the conductive material is boron.

Preferably, the cylindrical semiconductor is a silicon nitride cylinder.

Preferably, the silicon nitride cylinder has a radius of 95-110 um and a height of 85-95 um.

Preferably, the cylindrical semiconductor doped with the conductive material is prepared through the following steps.

### (S1) Pre-Treatment

A cylindrical silicon nitride substrate is pretreated.

### (S2) Sputtering

A boron target is subjected to magnetron co-sputtering in argon to deposit a boron-doped silicon nitride film on the cylindrical silicon nitride substrate, where during the magnetron co-sputtering, the cylindrical silicon nitride substrate is subject to a bias voltage.

### (S3) Annealing

The cylindrical silicon nitride substrate is subjected to photo-thermal annealing under nitrogen gas for 1-2 h.

### (S4) Cooling

The cylindrical silicon nitride substrate is cooled slowly to obtain a boron-doped cylindrical semiconductor.

In the actual manufacturing and operation processes, the wave band required by the product can be found by modifying the size, shape and conductivity of the sensor to test the absorption rate.

After the absorption resonance curve of the required wave band is plotted, the heat generated under the frequency corresponding to the highest absorption rate is tested.

The conductivity and size of the sensor are modified to reach the maximum absorption rate.

The conductivity of the silicon nitride film can be easily measured by using the thermoelectric performance measuring device such that a film with desired conductivity can be prepared.

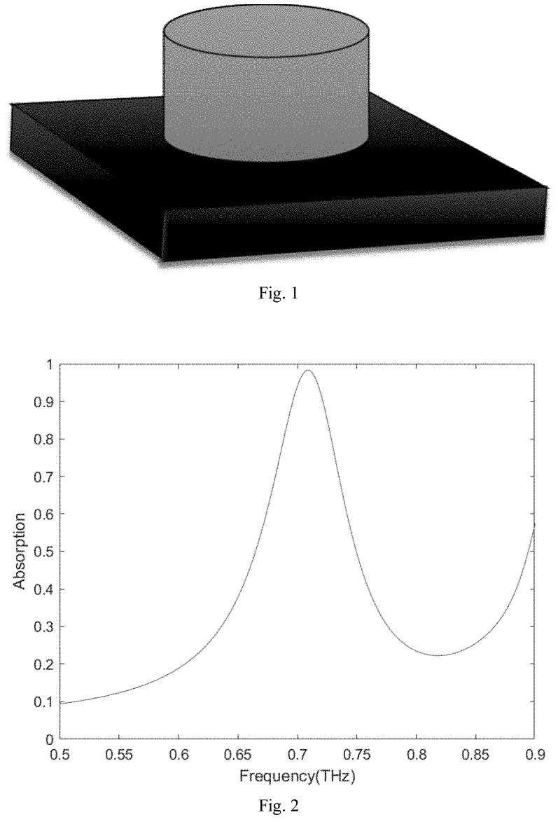

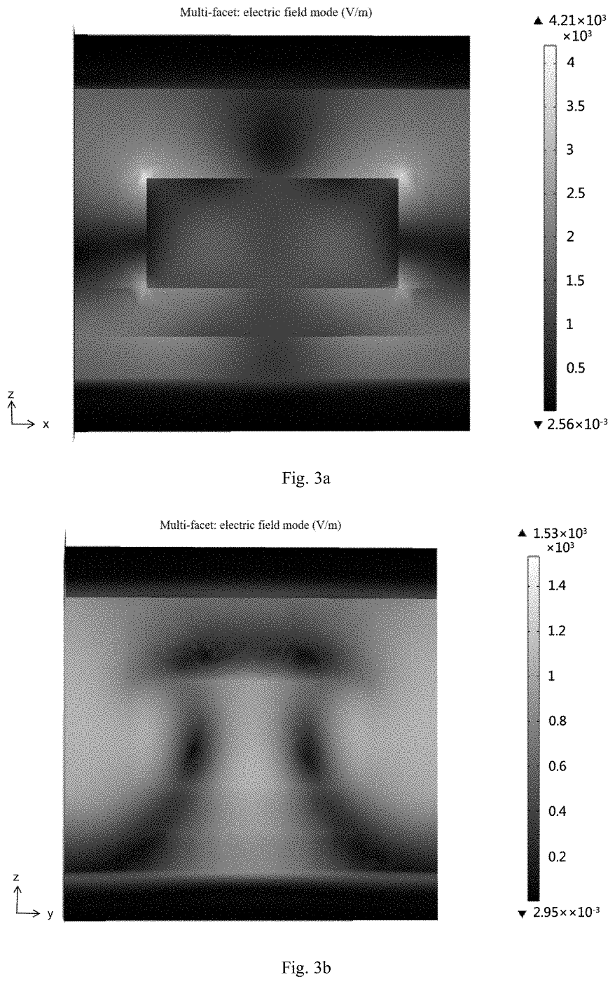

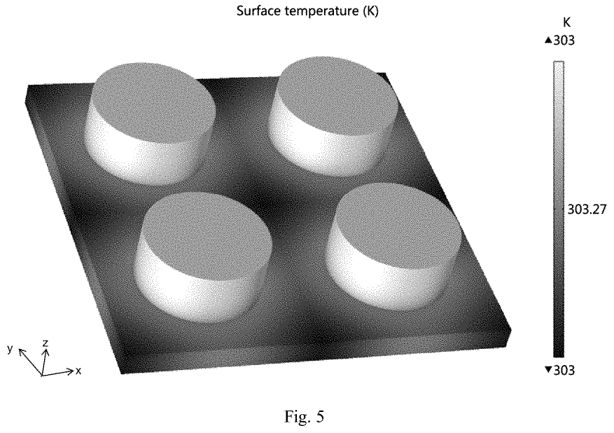

When the radius and height of the silicon nitride cylinder is 105 μm and 92 μm, respectively, the obtained simulation diagram is shown in FIGS. 3a-b. Referring to the simulation results shown in FIG. 2, the absorption rate of the model reaches 98% or more at 0.71 THz. Furthermore, as shown in FIG. 5, the simulation analysis shows the temperature distribution of the wave absorbing structure at a frequency of 0.71 THz and a port input power of 0.1 mW, where the highest temperature is up to 317.77 K.

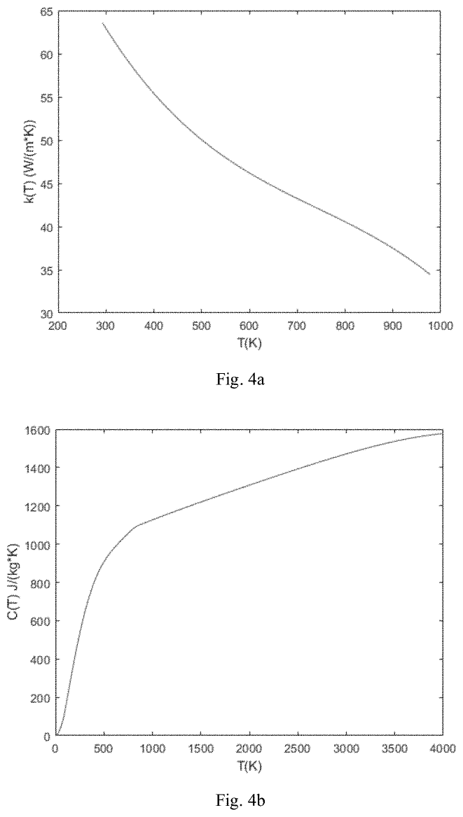

As shown in FIGS. 4a-b, the silicon nitride is heated by electromagnetic heat. The temperature increase will change some properties of the material. FIGS. 4a-b show characteristic change curves of the silicon nitride over temperature.

Boron is a poor conductor at room temperature and a good conductor at an elevated temperature. By doping a proper amount of boron in the silicon nitride cylinder, the conductivity of the silicon nitride can reach about 25 S/m.

The embodiments of this application demonstrate the absorptivity of the terahertz sensor and the temperature distribution under specific frequency and incident power. Though the infrared imaging detection is not illustrated herein, the specific operation should be understood by one of ordinary skill in the art.

Described above are merely illustrative of the disclosure, which are not intended to limit the disclosure. It should be understood that various changes, modifications, substitutions and variations made by one of ordinary skill in the art without departing from the principles and spirit of the present disclosure shall fall within the scope of the present disclosure defined by the appended claims.

What is claimed is:

1. A terahertz sensor based on a dielectric metasurface, comprising:
a sensing element; and
a thermosensitive circuit connected to the sensing element;
wherein the sensing element is composed of a cylindrical semiconductor doped with a conductive material; the conductive material is configured to change electrical conductivity of the cylindrical semiconductor to enable the cylindrical semiconductor to absorb electromagnetic waves in terahertz region; the terahertz sensor is micron-sized; the conductive material is boron; and the cylindrical semiconductor has a radius of 95-110 μm and a height of 85-95 μm; and
the cylindrical semiconductor doped with the conductive material is prepared through steps of:
(S1) pretreating a cylindrical silicon nitride substrate;
(S2) subjecting a boron target to magnetron co-sputtering in argon to deposit a boron-doped silicon nitride film on the cylindrical silicon nitride substrate, wherein during the magnetron co-sputtering, the cylindrical silicon nitride substrate is subject to a bias voltage; and
(S3) subjecting the cylindrical silicon nitride substrate to photo-thermal annealing under nitrogen gas for 1-2 h; and
(S4) cooling the cylindrical silicon nitride substrate to obtain a boron-doped cylindrical semiconductor.
